(19) United States
(12) Patent Application Publication
(10) Pub. No.: US 2015/0144975 A1
(43) Pub. Date: May 28, 2015

(54) LIGHT-EMITTING DEVICE

(71) Applicant: EPISTAR CORPORATION, Hsinchu (TW)

(72) Inventors: Fu-Chun TSAI, Hsinchu (TW); Wen-Luh LIAO, Hsinchu (TW); Yao-Ru CHANG, Hsinchu (TW); Shih-I CHEN, Hsinchu (TW); Chih-Chiang LU, Hsinchu (TW)

(73) Assignee: EPISTAR CORPORATION, Hsinchu (TW)

(21) Appl. No.: 14/088,705

(22) Filed: Nov. 25, 2013

(51) Int. Cl. H01L 33/30

(52) U.S. Cl. CPC H01L 33/30
USPC 257/98

(57) ABSTRACT

A light-emitting device comprises a substrate; and a semiconductor stack comprising a III-V group material formed on the substrate, wherein the substrate comprises a first amorphous portion adjacent to the semiconductor stack, and a portion having a material different from that of the first amorphous portion and away from the semiconductor stack, wherein the first amorphous portion has a first refractive index, the portion has a second refractive index, and the first refractive index is higher than the second refractive index and lower than a refractive index of the semiconductor stack.

### TECHNICAL FIELD

The application relates to a light-emitting device, and more particularly, to a light-emitting device comprising a substrate having an amorphous portion and a bulk portion having a material different from that of the amorphous portion.

### DESCRIPTION OF BACKGROUND ART

The light-emitting diode (LED) is a solid state semiconductor device. A structure of the light-emitting diode (LED) comprises a p-type semiconductor layer, an n-type semiconductor layer, and a light-emitting layer. The light-emitting layer is formed between the p-type semiconductor layer and the n-type semiconductor layer. The structure of the LED generally comprises group III-V compound semiconductor such as gallium phosphide, gallium arsenide, or gallium nitride. The light-emitting principle of the LED is the transformation of electrical energy to optical energy by applying electrical current to the p-n junction to generate electrons and holes. Then, the LED emits light when the electrons and the holes combine.

### SUMMARY OF THE APPLICATION

A light-emitting device comprises a substrate; and a semiconductor stack comprising a III-V group material formed on the substrate, wherein the substrate comprises a first amorphous portion adjacent to the semiconductor stack, and a bulk portion having a material different from that of the first amorphous portion and away from the semiconductor stack, wherein the first amorphous portion has a first refractive index, the bulk portion has a second refractive index, and the first refractive index is higher than the second refractive index and lower than a refractive index of the semiconductor stack.

### BRIEF DESCRIPTION OF THE DRAWINGS

FIG. 1 illustrates a cross-sectional view of a light-emitting device in accordance with first embodiment of the present application;

FIG. 2 illustrates a cross-sectional view of a light-emitting device being flipped and mounted to a support substrate in accordance with second embodiment of the present application; and

FIG. 3 illustrates a cross-sectional view of a packaged light-emitting device.

### DETAILED DESCRIPTION OF PREFERRED EMBODIMENTS

The embodiment of the application is illustrated in detail, and is plotted in the drawings. The same or the similar part is illustrated in the drawings and the specification with the same number.

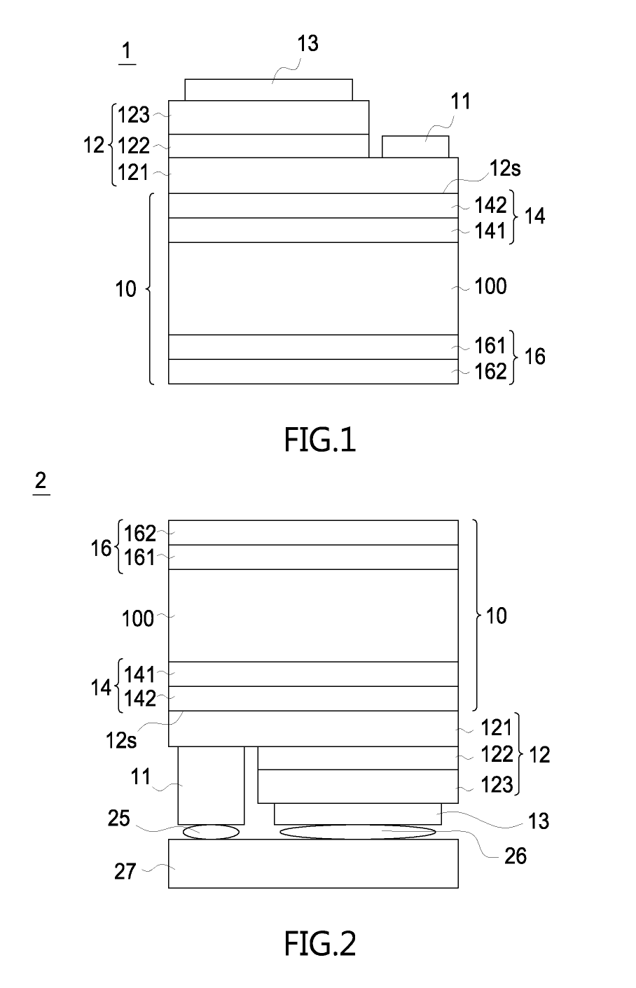

FIG. 1 illustrates a cross-sectional view of a light-emitting device 1 in accordance with first embodiment of the present application. The light-emitting device 1, such as a light-emitting diode (LED), comprises a substrate 10 and a semiconductor stack 12 formed on the substrate 10. The material of the semiconductor stack 12 comprises III-V group material doped with p-type impurity or n-type impurity. The semiconductor stack 12 comprises a first semiconductor layer 121 having a first conductivity type, such as n-type, a second semiconductor layer 123 having a second conductivity type different from the first conductivity type, such as p-type, and an active layer 122 formed between the first semiconductor layer 121 and the second semiconductor layer 123. The active layer 122 comprises a single heterostructure (SH), a double heterostructure (DH) or a multi-quantum well (MQW) structure. The semiconductor stack 12 may be formed by a known epitaxy method, such as metallic-organic chemical vapor deposition (MOCVD) method, molecular beam epitaxy (MBE) method, or hydride vapor phase epitaxy (HVPE) method. The electrons provided from the n-type semiconductor layer, such as the first semiconductor layer 121, and the holes provided from the p-type semiconductor layer, such as the second semiconductor layer 123, combine in the active layer 122 to emit a light under an external driving electrical current.

The semiconductor stack 12 is previously grown on a growth substrate (not shown), such as a GaAs substrate, and is then separated from the growth substrate and transferred to a permanent substrate, such as the substrate 10 shown in FIG. 1. The growth substrate can be removed by laser lift off or etching. The substrate 10 can be transparent to the light emitted from the active layer 122. The substrate 10 comprises a first amorphous portion 14 adjacent to the semiconductor stack 12, and a bulk portion 100 having a material different from that of the first amorphous portion 14 and away from the semiconductor stack 12. In accordance with an embodiment of the present application, the substrate 10 comprises a composite structure by stacking the first amorphous portion 14 on the bulk portion 100. The first amorphous portion 14 is insulative. The first amorphous portion 14 comprise a material other than III-V group material. The first amorphous portion 14 comprises an amorphous material. The amorphous material can be organic material, such as BCB or epoxy, inorganic material comprising oxygen element, nitrogen element or fluorine element, such as SiOₓN_{y}, SiOₓ, MgF₂, or CaF₂, or the combination thereof. The bulk portion 100 comprises a crystal material, such as Al₂O₃, ZnO, quartz or diamond, a non-crystal material, such as glass, acryl, or the combination thereof. In an example of the embodiment, the substrate 10 can be flexible by stacking the first amorphous portion 14 having the amorphous material, such as BCB or SiOₓN_{y}, on the bulk portion 100 having the non-crystal material, such as acryl.

The semiconductor stack 12 comprising III-V group material, such as GaP or AlGaInP, has a relative high refractive index, such as larger than 2.1. The bulk portion 100 has a refractive index lower than the refractive index of the semiconductor stack 12. For example, when the bulk portion 100 comprises Al₂O₃, the refractive index of Al₂O₃ is about 1.7. Because the difference of the refractive index between the semiconductor stack 12 and the bulk portion 100 is large, the light emitted from the active layer 12 is easily totally reflected at an interface between the semiconductor stack 12 and the bulk portion 100, and the amount of the light being absorbed by the MQW and lost at the interface increases.

As shown in FIG. 1, the first amorphous portion 14 is stacked on the bulk portion 100 and is on a side of the bulk portion 100 which is adjacent to the semiconductor stack 12. The first amorphous portion 14 acts as an adhesive agent connecting the bulk portion 100 and semiconductor stack 12. The first amorphous portion 14 also acts as an optical connection agent connecting the bulk portion 100 and semiconductor stack 12. The first amorphous portion 14 has a first refractive index which is lower than the refractive index of the semiconductor stack 12 and higher than the refractive index of the bulk portion 100. The first refractive index can be between 2.1 and 1.4. The first refractive index can be a gradient refractive index decreasing in a direction toward the bulk portion 100. The gradient refractive index can be changed continuously or stepwise such that a side of the first amorphous portion 14 near the semiconductor stack 12 has a higher refractive index than another side of the first amorphous portion 14 near the bulk portion 100.

The first amorphous portion 14 can be formed on the semiconductor stack 12 by plasma enhanced chemical vapor deposition (PECVD). For example, when the first amorphous portion 14 is SiOₓN_{y}, SiH₄, NH₃, N₂O, or N₂ can be used as a source gas. The refractive index of SiOₓN_{y} can be adjusted by changing the flowing rate of the source gas, or the ratio of SiH₄ and NH₃. When the ratio of SiH₄ and NH₃ is increased, the nitrogen composition of SiOₓN_{y} decreases such that the refractive index of SiOₓN_{y} also decreases. The first amorphous portion 14 can be formed on the semiconductor stack 12 at a temperature below 300° C., preferably below 150° C. The temperature below 300° C. protects the semiconductor stack 12 from being damaged by the heat. After the first amorphous portion 14 is formed on the semiconductor stack 12, the bulk portion 100 is thermally bonded to the first amorphous portion 14 or bonded to the first amorphous portion 14 by a pressure.

The first amorphous portion 14 can be a single layer structure or a multi-layer structure. FIG. 1 illustrates an embodiment that the first amorphous portion 14 is a multi-layer structure comprising a first sub-portion 141 and a second sub-portion 142. The amount of the sub-portions of the first amorphous portion 14 shown in FIG. 1 is just an embodiment, not intended to limit scope of the present application.

When the first amorphous portion 14 comprises SiOₓN_{y}, the first amorphous portion 14 has a slope content profile of nitrogen and the nitrogen composition of the first amorphous portion 14 decreases in a direction toward the bulk portion 100. As shown in FIG. 1, when the first amorphous portion 14 is a multi-layer structure comprising a plurality of sub-portions 141, 142, the nitrogen composition of the second sub-portion 142 is higher than that of the first sub-portion 141 such that the second sub-portion 142 has higher refractive index than the first sub-portion 141. For example, the first sub-portion 141 comprises SiNₓ having a refractive index at 2.17 and the second sub-portion 142 comprises SiOₓN_{y} having a refractive index at 1.78. When the first amorphous portion 14 is a single layer structure (not shown), a side of the first amorphous portion 14 near the semiconductor stack 12 has higher refractive index than another side of the first amorphous portion 14 near the bulk portion 100.

A thickness of the first amorphous portion 14 can be between 1000 angstroms and 2000 angstroms, such as 1600 angstroms, in order to provide sufficient adhesive force between the semiconductor stack 12 and the bulk portion 100. In another embodiment, when the light emitted from the semiconductor stack 12 has a wavelength λ, in order to reduce the anti-reflectivity and increase the light extraction efficiency, a thickness of the first amorphous portion 14 can be an integral of λ/4. In details, a thickness of each layer among the first amorphous portion 14, such as the first sub-portion 141 or the second sub-portion 142, is λ/4 when the first amorphous portion 14 is a multi-layer structure.

When the light is predominantly extracted from a side of the semiconductor stack 12 remote from the substrate 10, a surface 12s of the semiconductor stack 12 adjacent to the first amorphous portion 14 can be a rough surface which can be optionally roughened with a method, such as etching or printing, to increase the light extraction efficiency of the light-emitting device 1.

In order to further reduce the refractive index difference between the substrate 10 and the air, the substrate 10 further comprises a second amorphous portion 16 formed under the bulk portion 100 as shown in FIG. 1. The second amorphous portion 16 comprises a structure similar to that of the first amorphous portion 14, the same description is not described here and that can be referred to the description of the first amorphous portion 14. A major difference between the first amorphous portion 14 and the second amorphous portion 16 is that a second refractive index of the second amorphous portion 16 is lower that the refractive index of the bulk portion 100 and the first refractive index of the first amorphous portion 14. For example, the second refractive index of the second amorphous portion 16 is smaller than 1.8 and larger than a refractive index of an air. The second refractive index is a gradient refractive index decreasing with a distance away from the bulk portion 100. The gradient refractive index can be changed continuously or stepwise such that a side of the second amorphous portion 16 near the bulk portion 100 has higher refractive index than another side of the second amorphous portion 16 remote from the bulk portion 100.

The second amorphous portion 16 is an insulative structure and comprises a material other than the III-V group material. In an example of the embodiment, the second amorphous portion 16 comprises an amorphous material comprising oxygen element, nitrogen element, or fluorine element. For example, the second amorphous portion 16 comprises SiOₓN_{y}, SiOₓ, MgF₂, or CaF₂, or the combination thereof. The second amorphous portion 16 can be formed on the substrate 10 by plasma enhanced chemical vapor deposition (PECVD). Here, a thickness of the second amorphous portion 16 is not limited, because the second amorphous portion 16 does not need to provide adhesive force as the first amorphous portion 14 does. In order to reduce the anti-reflectivity and increase the light extraction efficiency, a thickness of the second amorphous portion 16 can be an integral of λ/4. In details, a thickness of each layer among the second amorphous portion 16, such as the third sub-portion 161 or the fourth sub-portion 162, is λ/4 when the second amorphous portion 16 is a multi-layer structure. When the second amorphous portion 16 is SiOₓN_{y}, the second amorphous portion 16 comprises a slope content profile of nitrogen, and the nitrogen composition of the second amorphous portion 16 decreases with a distance away from the bulk portion 100. The second amorphous portion 16 can be grown on the bulk portion 100 at a temperature below 300° C. The temperature below 300° C. protects the semiconductor stack 12, or the bulk portion 100, especially when the substrate 10 comprises a organic material like polyethylene terephthalate (PET), from being damaged by the heat. Similar to the first amorphous portion 14, the second amorphous portion 16 can be a single layer structure or a multi-layer structure. FIG. 1 illustrates an example that the second amorphous portion 16 is a multi-layer structure comprising a plurality of sub-portions, such as the third sub-portion 161 and the fourth sub-portion 162. The nitrogen composition of the third sub-portion 161 is higher than the nitrogen composition of the fourth sub-portion 162 such that the third sub-portion 161 has higher refractive index than the fourth sub-portion 162. For example, the third sub-portion 161 comprises SiOₓN_{y} having a refractive index at 1.6 and the fourth sub-portion 162 comprises SiOₓ having a refractive index at 1.46.

A first electrode 11 and a second electrode 13 are formed on a same side of the semiconductor stack 12. The second electrode 13 can be formed on the second semiconductor layer 123. The first electrode 11 can be formed on the first semiconductor layer 121 after performing an etching process on the semiconductor stack 12 to expose an area of the first semiconductor layer 121. The first electrode 11 and the second electrode 13 are respectively electrically connected to the first semiconductor stack 121 and the second semiconductor stack 123, and supply a power to the light-emitting device 1.

FIG. 2 illustrates a cross-sectional view of a light-emitting device 1 being flipped and mounted to a support substrate 27 in accordance with second embodiment of the present application. When the light-emitting device 1 is flipped mounted to the support substrate 27, the light is predominantly extracted from the substrate 10, and a surface 12s of the semiconductor stack 12 adjacent to the first amorphous portion 14 is preferably a flat surface. The first electrode 11 and the second electrode 13 are respectively connected to the first pad 25 and the second pad 26 of the support substrate 27.

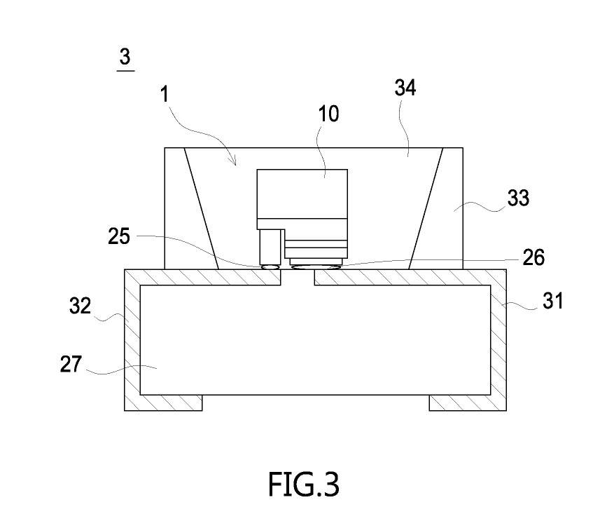

FIG. 3 illustrates a cross-sectional view of a packaged light-emitting device 3. The packaged light-emitting device 3 comprises a support substrate 27, a first connecting element 32, a second connecting element 31 and a reflector 33. The light-emitting device 1 of FIG. 1 is preferably flipped and mounted on the support substrate 27. A cavity 34 can be filled with an encapsulating material to protect the light-emitting device 1. The encapsulating material is preferably light transparent, such as silicone or epoxy. Also, a fluorescent material can be added into the encapsulating material. The first connecting element 32 and the second connecting element 31 are respectively electrically connected to the first electrode and the second electrode of the light-emitting device 1 through a first pad 25 and a second pad 26. With the first amorphous portion 14 and/or the second amorphous portion 16, the light of the light-emitting device 1 is more easily extracted to the outside.

The principle and the efficiency of the present application illustrated by the embodiments above are not the limitation of the application. Any person having ordinary skill in the art can modify or change the aforementioned embodiments. Therefore, the protection range of the rights in the application will be listed as the following claims.

What is claimed is:

1. A light-emitting device, comprising:
a substrate; and
a semiconductor stack comprising a III-V group material formed on the substrate, wherein the substrate comprises a first amorphous portion adjacent to the semiconductor stack, and a bulk portion having a material different from that of the first amorphous portion and away from the semiconductor stack,
wherein the first amorphous portion has a first refractive index, the bulk portion has a second refractive index, and the first refractive index is higher than the second refractive index and lower than a refractive index of the semiconductor stack.

2. The light-emitting device of claim 1, wherein the substrate further comprises a second amorphous portion having a third refractive index formed under the bulk portion, wherein the third refractive index is smaller than the second refractive index.

3. The light-emitting device of claim 2, wherein the first amorphous portion and/or the second amorphous portion comprise a material other than the III-V group material.

4. The light-emitting device of claim 2, wherein the first amorphous portion and/or the second amorphous portion comprise a material comprising oxygen element, nitrogen element, or fluorine element.

5. The light-emitting device of claim 1, wherein the refractive index of the semiconductor stack is larger than 2.1 and the first refractive index is between 2.1 and 1.4.

6. The light-emitting device of claim 2, wherein the third refractive index is smaller than 1.8 and larger than a refractive index of an air.

7. The light-emitting device of claim 2, wherein the first amorphous portion and/or the second amorphous portion comprises a single layer structure or a multi-layer structure.

8. The light-emitting device of claim 1, wherein the first refractive index is a gradient refractive index decreasing toward the bulk portion.

9. The light-emitting device of claim 2, wherein the third refractive index is a gradient refractive index decreasing with a distance away from the bulk portion.

10. The light-emitting device of claim 2, wherein the first amorphous portion and/or the second amorphous portion comprises SiOₓN_{y}, and the first amorphous portion and/or the second amorphous portion comprises a slope content profile of nitrogen.

11. The light-emitting device of claim 10, wherein the nitrogen composition of the first amorphous portion decreases toward the bulk portion, and the nitrogen composition of the second amorphous portion increases toward the bulk portion.

12. The light-emitting device of claim 2, wherein a thickness of the first amorphous portion is between 1000 angstroms and 2000 angstroms.

13. The light-emitting device of claim 2, wherein the light emitted from the semiconductor stack has a wavelength λ, and a thickness of the first amorphous portion and/or a thickness of the second amorphous portion is an integral of λ/4.

14. The light-emitting device of claim 1, wherein the substrate is flexible.

15. The light-emitting device of claim 1, wherein the substrate is transparent to a light emitted from the semiconductor stack.

16. The light-emitting device of claim 1, wherein the substrate is an insulative substrate.

17. The light-emitting device of claim 1, wherein a surface of the semiconductor stack adjacent to the first amorphous portion is a rough surface.

18. A light-emitting device, comprising:
a substrate having a refractive index;
a semiconductor stack comprising a III-V group material formed on the substrate;
a first amorphous portion having a first refractive index formed between the semiconductor stack and the substrate; and
a second amorphous portion having a second refractive index formed under the substrate, wherein the substrate is transparent to a light emitted from the semiconductor stack.

19. The light-emitting device of claim 18, wherein the first amorphous portion and/or the second amorphous portion comprise a material other than the III-V group material.

20. The light-emitting device of claim 18, wherein the refractive index of the substrate is larger than the first refractive index and smaller than second refractive index.
